(19) United States
(12) Patent Application Publication
(10) Pub. No.: US 2009/0078974 A1
(43) Pub. Date: Mar. 26, 2009

(54) Solid-state image capturing device; manufacturing method for the solid-state image capturing device; and electronic information device

(75) Inventors: Kenichi Nagai, Fukuyama-Shi (JP); Noboru Takeuchi, Fukuyama-Shi (JP); Kazuo Ootsubo, Fukuyama-Shi (JP); Yuji Hara, Fukuyama-Shi (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/229,915

(22) Filed: Aug. 28, 2008

(30) Foreign Application Priority Data
Aug. 30, 2007 (JP) 2007-224740

(51) Int. Cl. H01L 27/146; H01L 31/18

(52) U.S. Cl. 257/292; 438/70; 257/E27.133; 257/E31.127

(57) ABSTRACT

A solid-state image capturing device is provided with a plurality of light receiving elements arranged on a surface section of a semiconductor substrate, a color filter of each color for each of the plurality of light receiving elements, and a plurality of microlenses each for condensing incident light into each of the plurality of light receiving elements, in which the interlayer insulation film is provided directly below the color filter of each color in a state where a passivation and hydrogen sintering process film is removed from the interlayer insulation film.

This Nonprovisional application claims priority under 35 U.S.C. §119(a) on Patent Application No. 2007-224740 filed in Japan on Aug. 30, 2007, the entire contents of which are hereby incorporated by reference.

### BACKGROUND OF THE INVENTION

1. Field of the Invention

The present invention relates to a solid-state image capturing device, which is a semiconductor image sensor such as a CMOS image sensor and a CCD image sensor, that is constituted of semiconductor elements for performing photoelectric conversion on image light from a subject and capturing an image of the subject; a manufacturing method for the solid-state image capturing device, and an electronic information device, such as a digital camera (e.g., digital video camera and digital still camera), an image input camera, a scanner, a facsimile machine and a camera-equipped cell phone device, having the solid-state image capturing device as an image input device used in an image capturing section of the electronic information device.

2. Description of the Related Art

Conventionally, semiconductor image sensors, such as a CMOS image sensor and a CCD image sensor, are excellent for mass-production, and therefore, they are used as an image input device in a portable electronic information device, such as a digital camera including a digital video camera and a digital still camera, and a camera-equipped cell phone device.

Such a conventional portable electronic information device is driven by a battery. Therefore, it is important to realize a low voltage and a low power consumption design. Further, it is also important to reduce the cost, and to miniaturize the module size.

Therefore, a CMOS image sensor is in the limelight in the field of a solid-state image capturing device that is used for such a portable electronic information device because the CMOS image sensor has merits as follows: the CMOS image sensor consumes a lower power than a CCD image sensor; in addition, the cost can be reduced by using the conventional CMOS process technology; the module size can be miniaturized by manufacturing a pixel region, which includes sensor elements, and a peripheral circuit region, which includes a peripheral driving circuit (driver), on the same chip. Such a CMOS image sensor is introduced in Reference 1 and is shown in FIG. 23.

FIG. 23 is a longitudinal cross sectional view of essential parts of a conventional CMOS image sensor disclosed in Reference 1.

As shown in FIG. 23, a conventional CMOS image sensor 100 includes a P-type well region 102 provided on an N-type semiconductor substrate 101. In the P-type well region 102, a plurality of light receiving sections 103, which function as a plurality of photoelectric conversion storing section (each pixel section), are arranged at a predetermined interval and in a two dimensional matrix.

A plurality of wiring layers 104 to 106, which are formed with metal layers of aluminum and the like, are provided on the N-type semiconductor substrate 101 in such a manner to avoid covering the plurality of light receiving sections 103. The wiring layers 104 and 105 are provided inside a transparent, interlayer insulation film 107, such as SiO₂. The upper most wiring layer 106 is provided on an interlayer insulation film 107. A SiON film 108 for preventing reflection is provided on the wiring layer 106 and the interlayer insulation film 107, and further above, a plasma SiN film 109 is provided, the plasma SiN film functioning as a hydrogen supply source for reducing dark current at the time of sinter process. The plasma SiN film 109 also functions as a passivation film, which prevents the passing of any substances, such as water and a positive ion (e.g., Na ion and K ion), that have a harmful influence to a transistor region. Therefore, it is preferable to form the plasma SiN film 109 on the entire substrate. As described above, the SiON film 108 is provided as a reflection preventing film between the interlayer insulation film 107 and the plasma SiN film 109, the plasma SiN film 109 having a refractive index that ranges inbetween the refractive indexes of the interlayer insulation film 107 and the refractive indexes of the plasma SiN film 109.

Further, a color filter 110 with each of a plurality of colors is provided on the plasma SiN film 109 for each of the light receiving sections 103. Further, a microlens 111 is provided on the color filter 110 so as to condense the incident light on each of the light receiving sections 103.

In addition, a SiN film 113 is provided by being stacked on a SiO₂ film 112 formed on the entire substrate, and is provided in a corresponding location to each of the light receiving sections 103. The SiN film 113 functions as a reflection preventing film for reducing the reflection of incident light on the light receiving surface.

Signal readout circuits are provided for respective unit pixel sections, and are connected to one another via the wiring layers 104 to 106 described above. The signal readout circuits select each light receiving section 103 among the plurality of light receiving sections 103 of each line on a display screen and output a signal from each light receiving section 103. A contact section (not shown) is provided for electrical connection between vertical wiring layers in the signal readout circuit, as well as between the lower most wiring layer and an impurity diffusion region (not shown) on the substrate side, such as a charge detection section (floating diffusion FD), which will be described latter. The wiring layers 104 to 106 and the contact section (not shown) are buried by the interlayer insulation film 107. Herein, the wiring layers 104 to 106 and the contact section form a three layered, multilayered wiring layer.

A gate electrode (not shown), such as a transfer MOS transistor that constitutes the signal readout circuit, is formed at a predetermined position on the SiO₂ film 112 that is provided on the surface of the N-type semiconductor substrate 101. The charge detection section (floating diffusion FD), which is formed with an n-type (high concentration n-type: n+) semiconductor region, is formed under the SiO₂ film 112 and facing the light receiving section 103, which functions as a photoelectric conversion storing section. The charge detection section and the light receiving section 103 are arranged with the p-type well region 102 in between, where the p-type well region 102 is under a gate electrode (not shown) of the transfer MOS transistor so as to form a transistor channel region.

Reference 1: Japanese Laid-Open Publication No. 2006-156611

### SUMMARY OF THE INVENTION

According to the conventional constitution described above, the SiN film 113 is provided as a reflection prevention film on the light receiving section 103 so as to control the reflection on an interface of the Si/SiO₂ film 112 on the substrate surface. In addition, in order to increase a hydrogen sinter effect, the plasma SiN film 109 is used as a passivation film, which prevents the passing of any substances, such as water and a positive ion, that have a harmful influence to a transistor region. In order to control a color irregularity (sensitivity irregularity) due to multiple reflections between the SiN film 113 and the plasma SiN film 109, the SiON film 108 (refractive index of 1.7) is further provided as a reflection preventing film directly under the plasma SiN film 109.

However, the utilization efficiency of incident light is low because incident light is reflected outwards between the color filter 110 (refractive index of 1.6) and the plasma SiN film 109 (refractive index of 2.0). The transmission amount of the incident light is decreased due to the existence of the SiON film 108 and the plasma SiN film 109 described above. Further, the light receiving sensitivity is reduced because the distance between the microlens 111 and the substrate surface (light receiving section 103) is increased due to the existence of the SiON film 108 and the plasma SiN film 109. Further, according to the conventional technique described above, the color filter 110 is embedded in a recess between the wiring layers 106 on the interlayer insulation film 107 to planarize the surface. Therefore, the color filter 110 has a thick film-thickness, so that the transmission amount of the incident light is decreased and the light receiving sensitivity is further reduced. Although the multiple reflections between the plasma SiN film 109 and the substrate surface are reduced due to SiON film 108 for preventing reflection, which is positioned below the plasma SiN film 109, the multiple reflections still exist to some extent and the multiple reflections interfere each other. As a result, certain wavelength is emphasized and appears among the wavelengths of interfering light due to the unevenness of the film-thickness of the interlayer insulation film 107 so that the color irregularity and sensitivity irregularity occur.

The present invention is intended to solve the conventional problems described above. The objective of the present invention is to provide a solid-state image capturing device, in which outward reflection of incident light resulted from the plasma SiN film and the transmission amount of the incident light are reduced by completely removing the plasma SiN film, and at the same time, the distance between the microlens and the substrate surface is further reduced so as to improve the light receiving sensitivity, and further, the color irregularity and the sensitivity irregularity can be controlled by further reducing the multiple reflections of light between the microlens and the substrate surface. The further objective of the present invention is to provide a manufacturing method for the solid-state image capturing device, and an electronic information device, such as a cell phone device, using the solid-state image capturing device as an image input device in an image capturing section.

A solid-state image capturing device according to the present invention includes: a plurality of light receiving elements arranged on a surface section of a semiconductor substrate; a color filter of each color for each of the plurality of light receiving elements having an interlayer insulation film arranged therebetween; and a plurality of microlenses for condensing incident light into each of the plurality of light receiving elements, in which the interlayer insulation film is provided directly below the color filter of each color in a state where a passivation and hydrogen sintering process film on interlayer insulation film is removed, thereby achieving the objective described above.

Preferably, in a solid-state image capturing device according to the present invention, a plurality of multiple wiring layers are buried in the interlayer insulation film.

Still preferably, in a solid-state image capturing device according to the present invention, the interlayer insulation film is planarized up to and including a surface of an upper most layer of the multiple wiring layers.

Still preferably, in a solid-state image capturing device according to the present invention, the interlayer insulation film is planarized with a predetermined film-thickness retained above the surface of the upper most layer of the multiple wiring layers.

Still preferably, in a solid-state image capturing device according to the present invention, a pixel region, which includes the plurality of light receiving elements, and a peripheral circuit region, which is arranged around the pixel region and includes a driving circuit for selecting and signal-reading of the plurality of light receiving elements, are provided on the same chip, the passivation and hydrogen sintering process film is provided without being removed between the color filter of each color and the interlayer insulation film in the peripheral circuit region, and the passivation and hydrogen sintering process film is removed and the interlayer insulation film is provided directly below the color filter of each color in the pixel region.

Still preferably, in a solid-state image capturing device according to the present invention, when a refractive index difference between the color filter and the interlayer insulation film directly below the color filter is defined as n, such that the n is 0.4>n≧0.

Still preferably, in a solid-state image capturing device according to the present invention, the interlayer insulation film is a transparent material that has the same refractive index as the color filter.

Still preferably, in a solid-state image capturing device according to the present invention, the interlayer insulation film is a silicon oxide film or a low dielectric film.

Still preferably, in a solid-state image capturing device according to the present invention, the passivation and hydrogen sintering process film is a plasma SiN film.

Still preferably, in a solid-state image capturing device according to the present invention, the solid-state image capturing device is a CMOS solid-state image capturing device, in which a plurality of signal readout circuits are provided for each unit pixel section, the plurality of signal readout circuits are connected to each other by the multiple wiring layers, for selecting the light receiving elements and outputting a signal from the light receiving elements.

Still preferably, in a solid-state image capturing device according to the present invention, the plurality of signal readout circuits among the light receiving elements arranged in a matrix on the side of the semiconductor substrate including: a selection transistor for selecting a predetermined light receiving element; an amplifying transistor, which is connected to the selection transistor in series, for amplifying a signal voltage in accordance with a signal voltage, into which a signal charge being transferred from a selected light receiving element through a transfer transistor to a charge detection section is converted; and a reset transistor for resetting an electric potential of a charge detection section to a predetermined electric potential after the amplifying transistor outputs a signal.

Still preferably, in a solid-state image capturing device according to the present invention, the signal readout circuits among the light receiving elements arranged in a matrix on the side of the semiconductor substrate include: an amplifying transistor for amplifying a signal voltage in accordance with a converted signal voltage, into which a signal charge being transferred from a light receiving element selected from a peripheral circuit through a transfer transistor to a charge detection section is converted; and a reset transistor for resetting an electric potential of a charge detection section to a predetermined electric potential after the amplifying transistor outputs a signal.

Still preferably, in a solid-state image capturing device according to the present invention, a reflection preventing film is provided only above the light receiving element and having an insulation film arranged therebetween, and the interlayer insulation film is provided on the reflection preventing film.

Still preferably, in a solid-state image capturing device according to the present invention, the interlayer insulation film is directly provided above the light receiving element, having an insulation film arranged therebetween.

Still preferably, in a solid-state image capturing device according to the present invention, a waveguide tube is provided in the interlayer insulation film above the light receiving element so as to guide light from the microlens to the light receiving element.

Still preferably, in a solid-state image capturing device according to the present invention, the solid-state image capturing device is a CCD solid-state image capturing device, in which the plurality of light receiving elements are provided in two dimensions in a pixel region, and a signal charge photoelectrically converted in the light receiving elements is read out to a charge transfer section and is successively transferred in a predetermined direction.

A manufacturing method for a solid-state image capturing device according to the present invention includes a plurality of light receiving elements arranged on a surface section of a semiconductor substrate, a color filter of each color for each of the plurality of light receiving elements having an interlayer insulation film arranged therebetween, and a plurality of microlenses each for condensing incident light into each of the plurality of light receiving elements, the method including the steps of: forming a passivation and hydrogen sintering process film on the interlayer insulation film to perform a hydrogen sintering process, or performing a hydrogen sintering process in a hydrogen atmosphere without forming a passivation and hydrogen sintering process film on the interlayer insulation film; and removing the passivation and hydrogen sintering process film when the passivation and hydrogen sintering process film is formed on the interlayer insulation film.

Preferably, in a manufacturing method for a solid-state image capturing device according to the present invention, the method includes: a planarization process step of polishing and planarizing an upper most insulation layer of an interlayer insulation film down to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements, a hydrogen sintering process step of forming a passivation and hydrogen sintering process film on the whole substrate of the planarized insulation layer and performing a hydrogen sintering process by thermal treatment, a passivation and hydrogen sintering process film removing step of removing the passivation and hydrogen sintering process film in the pixel region by etching the passivation and hydrogen sintering process film in the pixel region with the passivation and hydrogen sintering process film retained in the peripheral circuit region after the hydrogen sintering process, and a color filter and microlens forming step of, in the pixel region, forming the color filter of each color directly on the planarized insulation layer and forming the microlens further on the color filter.

Still preferably, in a manufacturing method for a solid-state image capturing device according to the present invention, the method includes: a planarization process step of polishing and planarizing an upper most insulation layer of an interlayer insulation film with a predetermined film-thickness retained to a surface of an upper most wiring layer after the multiple wiring layers buried, in the interlayer insulation film in a pixel region, which includes the plurality of light receiving elements, and in a peripheral circuit region, which is arranged around the pixel region and includes a driving circuit for selecting and signal-reading of the plurality of light receiving elements, a hydrogen sintering process step of forming a passivation and hydrogen sintering process film on the whole substrate of the planarized insulation layer and performing a hydrogen sintering process by thermal treatment, a passivation and hydrogen sintering process film removing step of removing the passivation and hydrogen sintering process film in the pixel region by etching the passivation and hydrogen sintering process film in the pixel region with the passivation and hydrogen sintering process film retained only in the peripheral circuit region after the hydrogen sintering process, and a color filter and microlens forming step of, in the pixel region, forming the color filter of each color directly on the planarized insulation layer and forming the microlens further on the color filter.

Still preferably, in a manufacturing method for a solid-state image capturing device according to the present invention, the method includes: a planarization process step of polishing and planarizing an upper most insulation layer of an interlayer insulation film with a predetermined film-thickness retained to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements, a hydrogen sintering process step of forming a passivation and hydrogen sintering process film only on the peripheral circuit region and performing a hydrogen sintering process by thermal treatment, and a color filter and microlens forming step of, in the pixel region, forming the color filter of each color directly on the planarized insulation layer and forming the microlens further on the color filter after the hydrogen sintering process.

Still preferably, in a manufacturing method for a solid-state image capturing device according to the present invention, the method includes: a planarization process step of polishing and planarizing an upper most insulation layer of an interlayer insulation film with a predetermined film-thickness retained to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements, a hydrogen sintering process step of performing a hydrogen sintering process in a hydrogen atmosphere by thermal treatment without forming a passivation and hydrogen sintering process film on the peripheral circuit region and the pixel region, and a color filter and microlens forming step of, in the pixel region, forming the color filter of each color directly on the planarized insulation layer and forming the microlens further on the color filter after the hydrogen sintering process.

An electronic information device using any of the solid-state image capturing devices according to the present invention as an image input device in an image capturing section, thereby achieving the objective described above.

The function of the present invention with the constitutions described above will be described hereinafter.

According to the present invention, a hydrogen sintering process is performed by forming a passivation and hydrogen sintering process film on an interlayer insulation film. Alternatively, a hydrogen sintering process can be performed in a hydrogen atmosphere without forming a passivation and hydrogen sintering process film on an interlayer insulation film. When the passivation and hydrogen sintering process film is formed on the interlayer insulation film, the passivation and hydrogen sintering process film is removed after the hydrogen sinter process. As a result, the interlayer insulation film is provided directly below color filters for a plurality of colors and provided on a semiconductor substrate that has a plurality of light receiving elements, where the passivation and hydrogen sintering process film is removed from the interlayer insulation film.

As described above, unlike the conventional technique, where the plasma SiN film functions as a passivation and hydrogen sintering process film that is provided above the SiON film, the SiON film for preventing reflection and the plasma SiN film, for example, are not provided. By not providing such films, the transmissivity of incident light is improved. At the same time, the decreasing of the utilization efficiency of incident light, which is due to the outward reflection of incident light resulting from the plasma SiN film having a high refractive index, can be eliminated. The distance between the microlens and the substrate surface is further reducible by the thickness of the conventional SiON film and plasma SiN film due to the SiON film and plasma SiN film not being provided.

According to the present invention with the constitution described above, the SiON film for preventing reflection and the plasma SiN film, for example, that functions as a passivation and hydrogen sintering process film are either removed or not provided. Therefore, the problem of the outward reflection of incident light resulted from the plasma SiN film having a high refractive index and the problem of the decrease of the transmission amount due to the plasma SiN film itself are solved. At the same time, the distance between the microlens and the substrate surface is further reduced to improve the light receiving sensitivity. Further, the multiple reflections of light between the microlens and the substrate surface are further reduced to control the color irregularity and the sensitivity irregularity.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view showing an exemplary essential structure of a CMOS image sensor according to Embodiment 1 of the present invention.

FIG. 2 is a longitudinal cross sectional view of essential parts in the CMOS image sensor in FIG. 1, schematically showing a planarization treatment step for an interlayer insulation film.

FIG. 3 is a longitudinal cross sectional view of essential parts in the CMOS image sensor in FIG. 1, schematically showing a plasma SiN film forming and hydrogen sintering process step.

FIG. 4 is a longitudinal cross sectional view of essential parts in the CMOS image sensor in FIG. 1, schematically showing a plasma SiN film removing step.

FIG. 5 is a longitudinal cross sectional view of essential parts in the CMOS image sensor in FIG. 1, schematically showing a color filter and microlens forming step.

FIG. 6 is a longitudinal cross sectional view showing an exemplary essential structure of a CMOS image sensor according to Embodiment 2 of the present invention.

FIG. 7 is a longitudinal cross sectional view of essential parts in the CMOS image sensor in FIG. 6, schematically showing a planarization treatment step for an interlayer insulation film.

FIG. 8 is a longitudinal cross sectional view of essential parts in the CMOS image sensor in FIG. 6, schematically showing a plasma SiN film forming and hydrogen sintering process step.

FIG. 9 is a longitudinal cross sectional view of essential parts in the CMOS image sensor in FIG. 6, schematically showing a plasma SiN film removing step.

FIG. 10 is a longitudinal cross sectional view of essential parts in the CMOS image sensor in FIG. 6, schematically showing a color filter and microlens forming step.

FIG. 11 is a graph showing the light receiving sensitivities with a plasma SiN film and the light receiving sensitivities without the plasma SiN film in the CMOS image sensor in FIG. 6.

FIG. 12 is a longitudinal cross sectional view of essential parts in the CMOS image sensor according to Embodiment 3, schematically showing a planarization treatment step.

FIG. 13 is a longitudinal cross sectional view of essential parts in the CMOS image sensor according to Embodiment 3, schematically showing a plasma SiN film forming and hydrogen sintering process step.

FIG. 14 is a longitudinal cross sectional view of essential parts in the CMOS image sensor according to Embodiment 3, schematically showing a color filter and microlens forming step.

FIG. 15 is a longitudinal cross sectional view of essential parts in the CMOS image sensor according to a variation of Embodiment 3, schematically showing a planarization treatment and hydrogen sintering process step.

FIG. 16 is a longitudinal cross sectional view of essential parts in the CMOS image sensor according to a variation of Embodiment 3, schematically showing a color filter and microlens forming step.

FIG. 17 is a longitudinal cross sectional view schematically showing a unit pixel of a solid-state image capturing device in a CCD image sensor according to Embodiment 4 of the present invention.

FIG. 18 is a longitudinal cross sectional view showing an exemplary essential structure of a CMOS image sensor according to Embodiment 5 of the present invention.

FIG. 19 is a longitudinal cross sectional view showing an exemplary essential structure of a CMOS image sensor according to Embodiment 6 of the present invention.

FIG. 20 is a longitudinal cross sectional view showing an exemplary essential structure of a variation of a CMOS image sensor according to Embodiment 6 of the present invention.

FIG. 21 is a longitudinal cross sectional view showing an exemplary essential structure of another variation of a CMOS image sensor according to Embodiment 6 of the present invention.

FIG. 22 is a block diagram showing an exemplary diagrammatic structure of an electronic information device using any of the solid-state image capturing devices according to Embodiments 1 to 4 of the present invention in an image capturing section.

FIG. 23 is a longitudinal cross sectional view of essential parts in a conventional CMOS image sensor disclosed in Reference 1.

10, 10A, 10B, 10B′CMOS image sensor
11, 31 N-type semiconductor substrate
12, 32 P-type well region
13, 33 light receiving section (light receiving element)
13a, 33a surface P+ layer
14, 34 gate insulation film
15 SiN film
16 first insulation film
17 first wiring
18 second insulation film
19 second wiring
20 third insulation film
21 third wiring
22, 22A fourth insulation film (interlayer insulation film)
23, 41 color filter
24, 42 microlens
25 plasma SiN film
26 fourth wiring
27A fifth insulation film
27, 40 interlayer insulation film
30 CCD image sensor
32a charge readout section (transistor channel section)
36 gate
37 high concentration P-type layer (stopper section)
37a STI
38 insulation film
39 shield film
TF charge transfer section
50 electronic information device
60 solid-state image capturing apparatus
61 solid-state image capturing device
70 memory section
80 display section
90 communication section

### DESCRIPTION OF THE PREFERRED EMBODIMENTS

Hereinafter, Embodiment 1 to 3 will be described, where a solid-state image capturing device according to the present invention and a manufacturing method thereof are applied to a CMOS image sensor. Subsequently, Embodiment 4 will be described, where a solid-state image capturing device according to the present invention and a manufacturing method thereof are applied to a CCD image sensor, and Embodiment 5 of an electronic information device using any of the solid-state image capturing device according to Embodiments 1 to 4 as an image input device in an image capturing section, will be described. Embodiments will be described in detail with reference to the accompanying figures.

Herein, the characteristics of the CMOS image sensor and the CCD image sensor will be briefly described.

Unlike the CCD image sensor, which transfers a signal charge from each light receiving section by a vertical transfer section and transfers the signal charge from the vertical transfer section horizontally by a horizontal transfer section, the CMOS image sensor reads out a signal charge of each pixel from a light receiving section by a selection control line that is constituted of aluminum wiring, such as a memory device. The CMOS image sensor subsequently converts the signal charge into a voltage, and consecutively reads out an image capturing signal, which is amplified in accordance with the converted voltage, from selected pixels. On the one hand, the CCD image sensor requires a plurality of positive and negative power supply voltage for driving the CCD. On the other hand, the CMOS image sensor is drivable with a single power supply, and low power consumption and low voltage driving are possible compared to the CCD image sensor. Further, manufacturing for the CCD image sensor uses a unique CCD manufacturing process. Therefore, it is difficult to simply apply a general manufacturing process of a CMOS circuit for the CCD image sensor. In addition, a logic circuit, an analog circuit, an analog-digital converting circuit and the like are formed at the same time in the CMOS process frequently used for manufacturing a display controlling driver circuit, an image capturing controlling driver circuit, a semiconductor memory including DRAM, and a logic circuit since a general manufacturing process for a CMOS circuit is used for the CMOS image sensor. Therefore, it is easy to form the CMOS image sensor together with a semiconductor memory, a display controlling driver circuit, and an image capturing controlling driver circuit on the same semiconductor chip. It is also easy in manufacturing the CMOS image sensor to share the same production line for a semiconductor memory, a display controlling driver circuit, and an image capturing controlling driver circuit.

### Embodiment 1

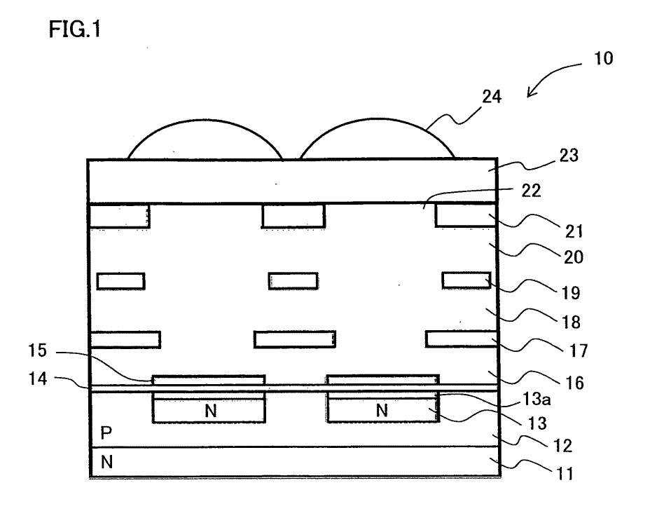

FIG. 1 is a longitudinal cross sectional view showing an exemplary essential structure of a CMOS image sensor according to Embodiment 1 of the present invention.

In FIG. 1, a P-type well region 12 is provided on an N-type semiconductor substrate 11 of a CMOS image sensor 10 according to Embodiment 1. A plurality of light receiving sections 13 are arranged at a predetermined interval in a two dimensional matrix in the P-type well 12, the light receiving sections 13 functioning as a plurality of N-type photoelectric conversion storing section (each pixel section; light receiving element). A surface P+ layer 13a for preventing dark current is provided on the surface of each light receiving section 13, having a light receiving element (photodiode) embedded structure. A gate insulation film 14, which is a SiO₂ film, is provided on the entire substrate. A SiN film 15 is provided as a reflection preventing film for reducing the reflection on a light receiving surface of the light receiving section 13, on the gate insulation film 14 only for each light receiving section 13.

A charge transfer region (P-type well region 12), functioning as a channel region of a charge transfer transistor, is provided adjacent to the light receiving section 13 so as to transfer a signal charge, which is photoelectrically converted in the light receiving section 13, to a floating diffusion FD (not shown) functioning as a charge detecting section (charge voltage converting section). A transfer gate electrode (not shown) is provided above the charge transfer region with the gate insulation film 14 arranged therebetween.

A wiring layer of a signal readout circuit is provided on the transfer gate electrode (not shown) in a manner to avoid covering the light receiving section 13. The signal readout circuit section has a function to convert the signal charge transferred from the light receiving section 13 to the floating diffusion FD into voltage, to amplify the converted voltage, and to read out the amplified voltage to a signal line as an image capturing signal from each pixel section.

Regarding the wiring layer of the signal readout circuit, a first insulation film 16 is formed above the entire substrate. A first wiring 17 is formed on the first insulation film 16, the second insulation film 18 is formed on the first wiring 17, and a second wiring 19 is formed on the second insulation film 18. Similarly, on the second wiring 19, a third insulation film 20, a third wiring 21, and a fourth insulation film 22 are formed respectively. As interlayer insulation films, the surfaces of the first insulation film 16, the second insulation film 18, the third insulation film 20 and the fourth insulation film 22 are planarized after each wiring is embedded. In particular, the fourth insulation film 22 is polished down to the surface of the third wiring 21 so that the third wiring 21 and the fourth insulation film 22 are planarized to be flush with each other. Although not shown, a first contact plug is formed in the first insulation film 16 so that an impurity diffusion region on the side of the substrate such as the floating diffusion FD, a drain region, a source region and a gate region that constitute a transistor on the side of the substrate, and the first wiring 17 are electrically connected as necessary. Further, a second contact plug is formed in the second insulation film 18 so that the first wiring 17 and the second wiring 19 are electrically connected as necessary. A third contact plug is formed in the third insulation film 20 so that the second wiring 19 and the third wiring 21 are electrically connected as necessary. As a result, the wirings in the signal readout circuit are electrically connected in a vertical direction.

In addition, a color filter 23 of each of the colors of R, G and B, which are arranged in accordance with each light receiving section 13, is directly provided on the planarized third wiring 21 and fourth insulation film 22, without having a conventional SiON film for preventing reflection or without having a plasma SiN film for passivation and hydrogen sintering. A microlens 24 for condensing light to each light receiving section 13 is provided on the color filter 23. Thus, such a conventional SiON film or plasma SiN film is not provided, so that the outward reflection of incident light resulted from the plasma SiN film and the transmission amount of the incident light are reduced. At the same time, the distance between the microlens and the substrate surface is further reduced to improve the light receiving sensitivity. In addition, between the microlens 24 and the substrate surface, the multiple reflections of light resulted from the plasma SiN film is eliminated so that the color irregularity and the sensitivity irregularity are controlled.

For example, the CMOS image sensor 10 according to Embodiment 1 can be manufactured as follows.

First, the gate insulation film 14 is formed on the entire surface of the N-type semiconductor substrate 11. Impurity ion is implanted from above to form the P-type well region 12. A gate electrode such as a transfer gate electrode (not shown) is formed in a predetermined position. Impurity ion is implanted in a predetermined position in the P-type well region 12 to form impurity diffusion regions, such as a plurality of N-type light receiving sections 13 and a floating diffusion FD, which are oppositely arranged with the P-type well region 12 therebetween and are below the transfer gate electrode. Further, the surface P+ layer 13a for preventing dark current is formed so as to cover the surface side of the light receiving section 13. Further, the SiN film 15 is formed as a reflection preventing film in a position corresponding to the light receiving surface of the light receiving section 13 on the gate insulation film 14.

Next, an SiO₂ film is film-grown as the first insulation film 16 on the entire substrate, which includes the gate electrode (not shown) and the SiN film 15, with an SiO₂ material, such as BPSG (boron phosphorus silicate glass. and high density plasma SiO₂ (HDP-SiO₂).

Further, in order to form the first contact plug, photosensitive resist material is applied on the first insulation film 16 so that a predetermined form is patterned by exposure and development, and anisotropic etching is performed on the first insulation film 16 using the patterned resist film as a mask, where the pattern of the resist mask film is made with a shape of the first contact plug. Subsequent to the etching of the first insulation film 16 using the resist mask film, a metal film, such as aluminum and tungsten, for a contact plug is grown by metal sputtering. The metal film for a contact plug can also be grown by CVD of aluminum and tungsten, for example. In addition, in order to prevent silicidation on the ground, a barrier metal film is sputtered prior to the metal sputtering. Subsequently, the entire surface of the first insulation film 16 is etched to remove a sputtering film on the first insulation film 16. As a result, the first contact plug (not shown) is formed, the contact plug filled in a hole (contact hole) of the first insulation film.

Further, in order to form the first wiring 17 on the substrate section having the first contact plug formed thereon, a metal film, such as aluminum, is film-grown by metal sputtering. Subsequently, a photosensitive resist film is applied thereon so as to pattern the photosensitive resist film in a predetermined form by exposure and development. Anisotropic etching is performed on the metal film using the patterned resist film as a mask so as to form the first wiring 17.

Similarly, the second insulation film 18, the second contact plug (not shown), the second wiring 19, and further, the third insulation film 20, the third contact plug (not shown), the third wiring 21, and the fourth insulation film 22 are formed respectively.

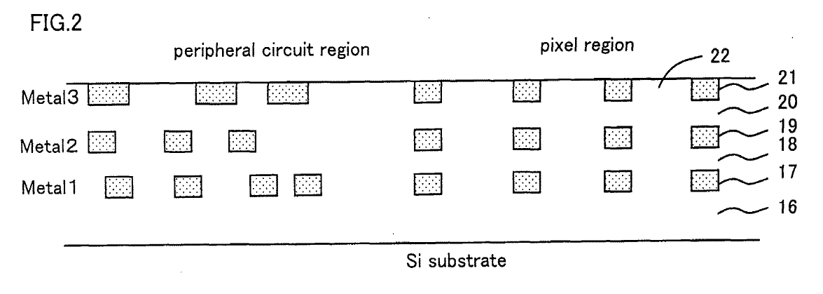

Next, as shown in FIG. 2, three layers of multi-layered wiring layers, which are embedded in the interlayer insulation film, are formed in a peripheral circuit region and a pixel region, where the peripheral circuit region including a driver circuit for controlling the drive of the signal readout circuit, and the pixel region being inside the peripheral circuit region and including the light receiving section 13 and the signal readout circuit for reading out a signal from the light receiving section 13. Subsequently, the fourth insulation film 22 is polished down to the surface of the third wiring 21 by a CMP treatment, so that the third wiring 21 and the fourth insulation film 22 are planarized to be flush with each other.

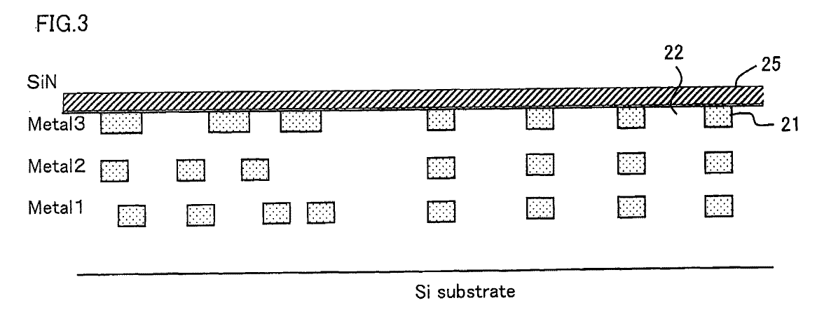

Subsequently, as shown in FIG. 3, a plasma SiN film 25 is formed above the entire substrate (on the planarized fourth insulation film 22 and third wiring 21) and a hydrogen sintering process is performed with a thermal treatment of the atmospheric temperature of about 400 to 500 degree Celsius. The plasma SiN film 25 functions as a passivation film, which prevents the passing of any substances, such as water and a positive ion, that have a harmful influence to a transistor region, and the plasma SiN film 25 also functions as a hydrogen supply source for reducing dark current at the time of sinter process. As a result, hydrogen from the plasma SiN film 25 is adsorbed by a silicon dangling bond on the surface of the silicon substrate so that dark current is reduced. At the same time, an ohmic contact is established between the first wiring 17 and an impurity diffusion region on the substrate side (such as the floating diffusion FD).

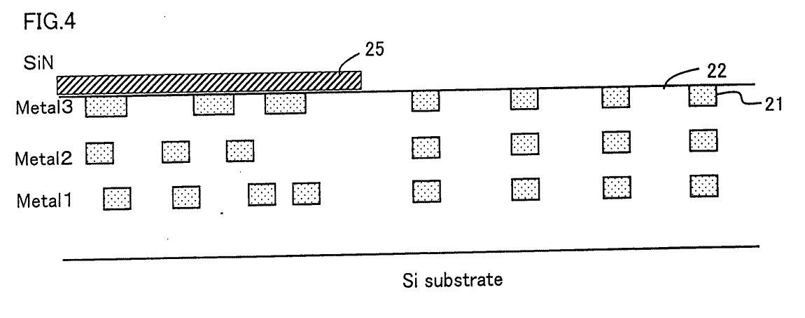

Subsequent to the hydrogen sintering process, the plasma SiN film 25 on the fourth insulation film 22 and the third wiring 21 in the pixel region is removed by etching so as to keep the plasma SiN film 25 only in the peripheral circuit region, as shown in FIG. 4.

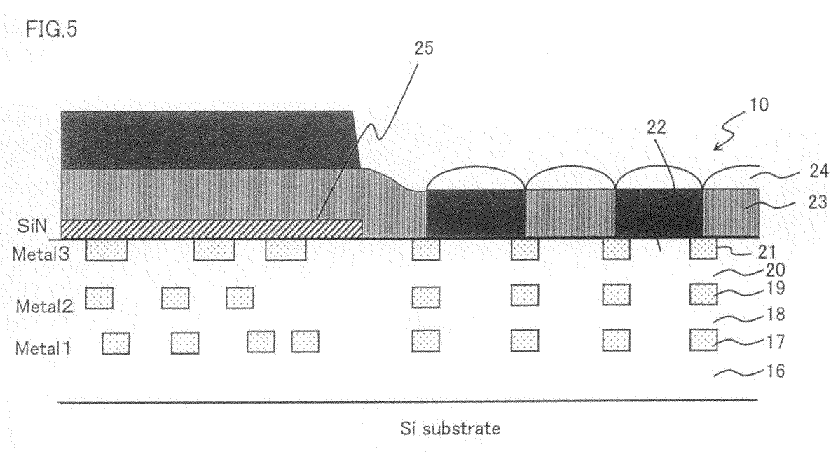

Further, as shown in FIG. 5, the color filter 23, which is arranged for each of the respective colors corresponding to each light receiving section 13, is directly formed on the planarized fourth insulation film 22 and third wiring 21. The microlens 24 is formed directly on the color filter 23. At this stage, the color filter 23 of one color among a plurality of colors is formed on the planarized fourth insulation film 22, the third wiring 23 and the plasma SiN film 25 in the peripheral circuit region, and the color filter 23 of a different color among a plurality of colors is formed thereon. In this case, two layers of color filters 23 of red and blue, for example, are laminated on the plasma SiN film 25 in the peripheral circuit region to shield the light. Thus, the CMOS image sensor 10 according to Embodiment 1 is manufactured. Note that the two layers of color filters 23 of red and blue, which are formed on the plasma SiN film 25 in the peripheral circuit region, may be two layers of color filters 23 of different colors among a plurality of colors (red, blue and green), or may be one layer of a color filter 23 of one color. In addition, instead of two layers of color filters 23 of red and blue, one layer of a color filter of black may be laminated on the plasma SiN film 25 in the peripheral circuit region.

According to Embodiment 1 with the structure described above, the conventional SiON film for preventing reflection and the plasma SiN film 25 for a passivation and hydrogen sintering process are not provided. Therefore, there is no transmission of incident light through the plasma SiN film 25, so that the transmissivity is improved. At the same time, the outward reflection of incident light due to the plasma SiN film 25 is eliminated. Further, the distance between the microlens 24 and the substrate surface is further reduced due to the absence of the conventional SiON film and the plasma SiN film, so that an Airy's disk radius becomes smaller, and the light collection efficiency and the light receiving sensitivity are improved. In addition, the multiple reflections of light resulted from the plasma SiN film 25 between the microlens 24 and the substrate surface is eliminated, so that the color irregularity and the sensitivity irregularity are controlled.

The outward reflection of incident light due to the plasma SiN film 25 will be described herein. Due to the plasma SiN film 25, the light that has passed from the microlens 24 to the color filter 23 (refractive index of 1.6) is reflected by the plasma SiN film 25 (refractive index of 2.0), so that incident light is wasted outwardly. However, if the plasma SiN film 25 is not provided, the reflection hardly takes place at the interface between the color filter 23 (refractive index of 1.6) and the underneath fourth insulation film 22 (silicon oxide film; refractive index of 1.5). Therefore, such a wasting of incident light will not occur and the incident light can be efficiently utilized. Compared to the conventional case having the plasma SiN film 25, with n defined as the refractive index difference and 0.4>n≧0, the incident light can be used more efficiently than the conventional case. With a material that has a refractive index similar to the refractive index of color filter 23, a low dielectric film may be used as the first to fourth insulation films (interlayer insulation films) instead of the silicon oxide film. The light receiving sensitivity can be improved with this structure, as well.

Further, the effect of controlling the dark current is maintained and is not impaired because, subsequent to the formation of the plasma SiN film 25, the hydrogen sintering process is performed and the plasma SiN film 25 in the pixel region (only the region for taking in the light) is removed. In addition, there is no problem regarding the effect for blocking water to the substrate side because the color filter 23 and the microlens 24, both of which have a passivation effect, are provided even if the plasma SiN film 25 functioning as a passivation film is not provided.

Further, when the conventional color filter is provided, such a color filter not only has a thick film, but also has steps. Because of the steps, the incident light reflects diffusely and outwardly, so that the incident light is wasted and a cross talk to adjacent pixels may also occur.

According to Embodiment 1, the color filters arranged for respective colors are formed directly on the fourth insulation film 22, which is planarized down to the surface of the third wiring 21, and the third wiring 21. But the present invention is not limited to this, and the color filters arranged for respective colors may be formed directly on the fourth insulation film 22 that is planarized for a predetermined thickness from the surface of the fourth insulation film 22 to the surface of the third wiring 21. In such a case, the distance between the microlens 24 and the substrate surface can be reduced and the light receiving sensitivity can be improved if the film thickness of the fourth insulation film 22 on the third wiring 21 is thinner than the total film thickness of the conventional SiON film and the plasma SiN film 25. Such a case will be described in the following Embodiment 2.

### Embodiment 2

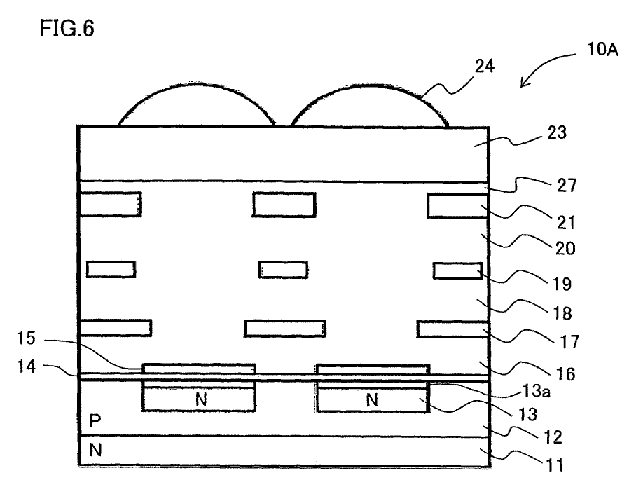

FIG. 6 is a longitudinal cross sectional view showing an exemplary essential structure of a CMOS image sensor according to Embodiment 2 of the present invention. The same reference numerals are used for the structural members that indicate the same functional effects as those of the structural members in FIG. 1.

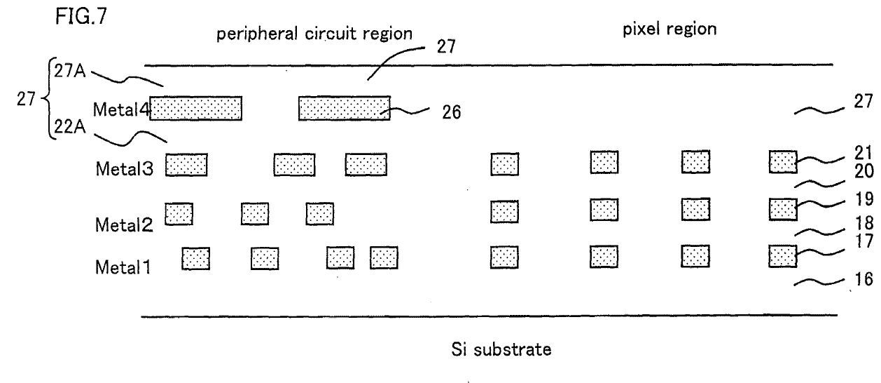

In a CMOS image sensor 10A according to Embodiment 2, a signal readout circuit converts a signal charge from a light receiving section 13 into a charge voltage and reads out an image capturing signal, which is amplified in accordance with the converted charge voltage, to a signal line. In FIG. 6, regarding the wiring layer of the signal readout circuit, a first insulation film 16 is formed above the substrate. A first wiring 17 is formed on the first insulation film 16, the second insulation film 18 is formed on the first wiring 17, and a second wiring 19 is formed on the second insulation film 18. Similarly, on the second wiring 19, a third insulation film 20, a third wiring 21, and a fourth insulation film 22 are formed respectively so as to constitute three layers of multiple wiring layers. As described above, three layers of multiple wiring layers are provided in the pixel region. In Embodiment 1 described above, three layers of multiple wiring layers are provided in the peripheral circuit region in the periphery of the pixel region. On the other hand, four layers of multiple wiring layers are provided in the peripheral circuit region in the periphery of the pixel region in Embodiment 2 as shown in FIG. 7. In addition, a fourth wiring 26 is formed on a fourth insulation film 22A, and a fifth insulation film 27A is formed on the fourth wiring 26, whose surface is planarized. An interlayer insulation film 27 is constituted of the fourth insulation film 22A and the fifth insulation film 27A.

A color filter 23 of each color of R, G and B, which is arranged for each light receiving section 13, is provided directly on the planarized fifth insulation film 27A, without having a conventional SiON film for preventing reflection or a plasma SiN film for passivation and hydrogen sintering arranged therebetween. A microlens 24 for condensing light to each light receiving section 13 is provided on the color filter 23. Thus, the conventional SiON film and plasma SiN film are removed, so that the multiple reflections of light resulted from the plasma SiN film is reduced between microlens 24 and the substrate surface and the light irregularity and the sensitivity irregularity are controlled. At the same time, the outward reflection and transmission of incident light due to the plasma SiN film is eliminated, and the distance between the microlens 24 and the substrate surface is further reduced due to the absence of the SiON film and the plasma SiN film. As a result, the light receiving sensitivity of the light receiving section 13 is improved. In order to further reduce the distance between the microlens 24 and the substrate surface in such a case, the interlayer insulation film 27 in the pixel region may be polished deeper, so that the surfaces of the third wiring 21 and the fourth insulation film 22 are planarized to be flush with each other as described in Embodiment 1. However, a predetermined film thickness of the fourth insulation film 22A is the distance between the surface of the fourth wiring 26 and the surface of the third wiring 21. In any case, a better planarization can be achieved and the color filters 23 of respective colors can be formed more easily with the predetermined film thickness of the fourth insulation film 22A.

For example, the CMOS image sensor 10A according to Embodiment 2 can be manufactured as follows.

As shown in FIG. 7, four layers of multi-layered wiring layers, which are embedded in the interlayer insulation film, are formed in a peripheral circuit region and in a pixel region, the peripheral circuit region including a driver circuit for controlling the drive of the signal readout circuit, and a pixel region being inside the peripheral circuit region and including the light receiving section 13 for each pixel and the signal readout circuit. Subsequently, the fifth insulation film 27A is polished and planarized by a CMP treatment.

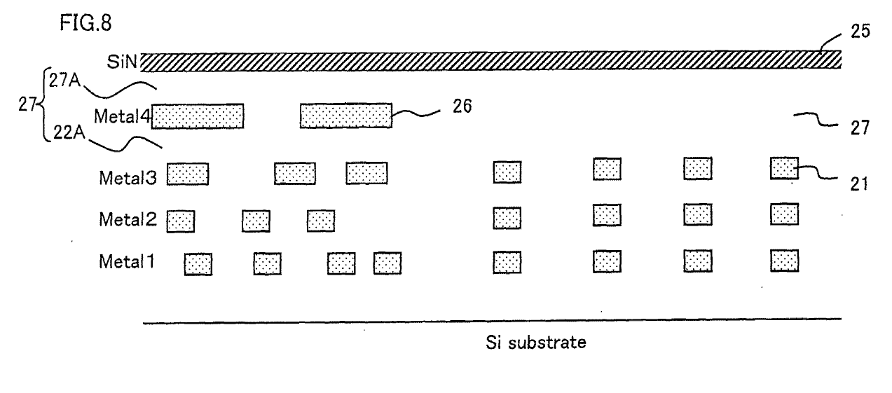

Subsequently, as shown in FIG. 8, a plasma SiN film 25 is formed above the entire substrate on the planarized fifth insulation film 27A, and a hydrogen sintering process is performed with a thermal treatment of the atmospheric temperature of about 400 to 500 degree Celsius, The plasma SiN film 25 functions as a passivation film, which prevent the passing of any substances, such as water and a positive ion (the transistor characteristic is deteriorated by Na ion, K ion and the like), that have a harmful influence to a transistor region, and the plasma SiN film 25 also functions as a hydrogen supply source for reducing dark current at the time of sinter process. As a result, hydrogen from the plasma SiN film 25 is adsorbed by a silicon dangling bond on the surface of the silicon substrate so that dark current is reduced. At the same time, an ohmic contact is established between the first wiring 17 and an impurity diffusion region on the substrate side (such as the floating diffusion FD).

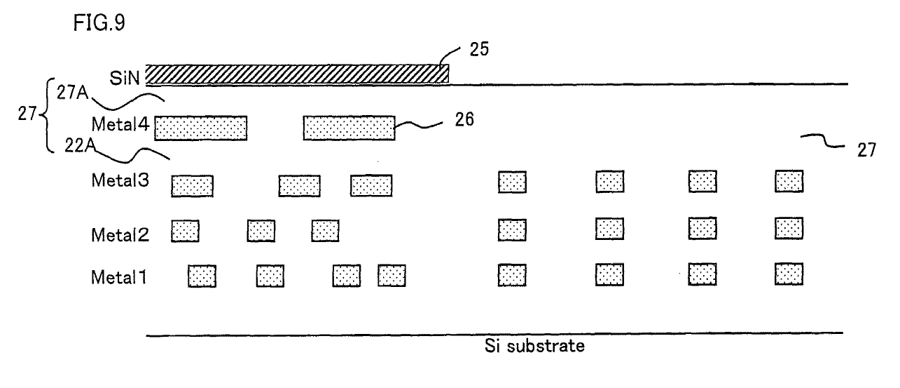

Subsequent to the hydrogen sintering process, the plasma SiN film 25 on the fifth insulation film 27A in the pixel region is removed by etching so as to keep the plasma SiN film 25 only in the peripheral circuit region, as shown in FIG. 9.

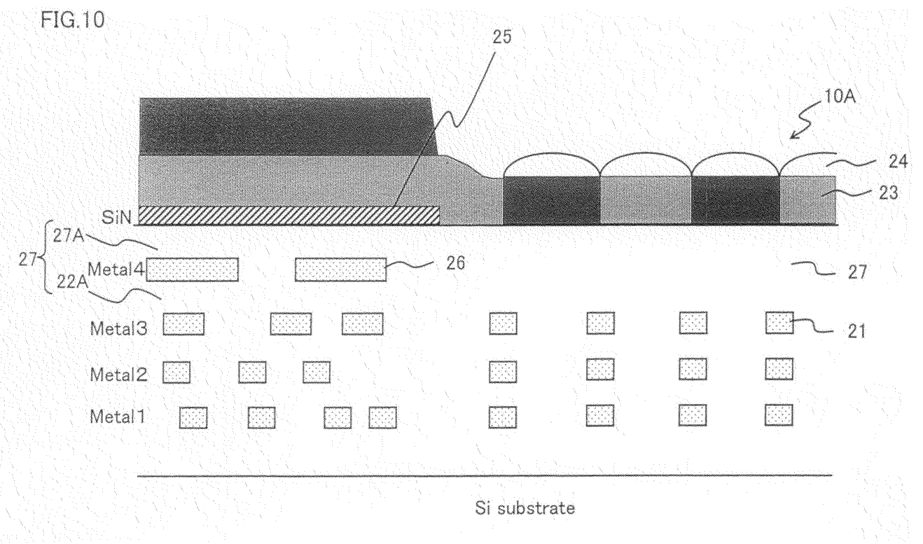

Further, as shown in FIG. 10, the color filter 23 arranged for each color is formed directly on the planarized fifth insulation film 27A in the pixel region. The microlens 24 is formed directly on the color filter 23. At this stage, a color filter 23 of one color among a plurality of colors is formed on the planarized fifth insulation film 27A and the plasma SiN film 25, and a color filter 23 of another color among a plurality of colors is formed thereon in the peripheral circuit region. In this case, two layers of color filters 23 of red and blue, for example, are laminated on the plasma SiN film 25 in the peripheral circuit region to shield the light. Thus, the CMOS image sensor 10A according to Embodiment 2 is manufactured. Note that the two layers of color filters 23 of red and blue, which are formed on the plasma SiN film 25 in the peripheral circuit region, may be two layers of color filters 23 of different colors among a plurality of colors (red, blue and green), or may be one layer of a color filter 23 of one color. In addition, instead of two layers of color filters 23 of red and blue, one layer of a color filter of black may be laminated on the plasma SiN film 25 in the peripheral circuit region.

According to Embodiment 2 with the structure described above, the conventional SiON film for preventing reflection and the plasma SiN film 25 for a passivation and hydrogen sintering are not provided. Therefore, the multiple reflections of light resulted from the plasma SiN film (not shown) is eliminated between the microlens 24 and the substrate surface, so that the color irregularity and the sensitivity irregularity are controlled. Further, the transmissivity of the incident light is improved since there is no plasma SiN film 25 provided. At the same time, the outward reflection of the incident light does not occur, and the distance between the microlens 24 and the substrate surface is further reduced due to the absence of the conventional SiON film and the plasma SiN film, so that the light receiving sensitivity is improved.

The outward reflection of the incident light will be described herein. Due to the plasma SiN film 25, the light that has passed from the microlens 24 to the color filter 23 (refractive index of 1.6) is reflected by the plasma SiN film 25 (refractive index of 2.0), so that incident light is wasted outwardly. However, if the plasma SiN film 25 is not provided, the reflection hardly takes place at the interface between the color filter 23 (refractive index of 1.6) and the underneath fourth insulation film 22 (silicon oxide film; refractive index of 1.5). Therefore, such a wasting of the incident light will not occur and the incident light can be efficiently utilized. Compared to the conventional case having the plasma SiN film 25, with n defined as the refractive index difference and 0.4>n≧0, the incident light can be used more efficiently than the conventional case. As a material that has a refractive index similar to the refractive index of color filter 23, a low dielectric film may be used as the first to fifth insulation films (interlayer insulation films) instead of the silicon oxide film. The light receiving sensitivity (mV) can be improved with this structure, as well.

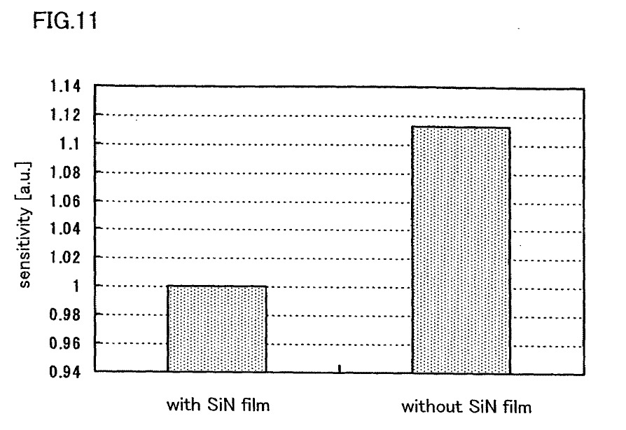

The improvement on the light receiving sensitivity described above is examined between the case where the plasma SiN film 25 is provided and the case the plasma SiN film 25 is not provided. As shown in FIG. 11, when there is no plasma SiN film 25 provided, the light receiving sensitivity (mV) is improved by about 11 to 12 percent compared to the case where the plasma SiN film 25 is provided.

Further, as described in Embodiment 2, the planarization can be performed more favorably and, as a result, the color filter can be formed more favorably when the color filter 23 arranged for each color is formed directly on the planarized fourth insulation film 22 with a predetermined thickness from the surface of the fourth insulation film 22 to the surface of the third wiring 21, compared to when the color filter 23 arranged for each color is formed directly on the fourth insulation film 22, which is planarized down to the surface of the third wiring 21, and the third wiring 21 as described in Embodiment 1.

According to Embodiments 1 and 2, after the plasma SiN film 25 is provided and the hydrogen sintering process is performed, the plasma SiN film 25 is removed from the pixel region. But the present invention is not limited to this, and the hydrogen sintering process may be performed without providing the plasma SiN film 25. Such a case will be described in Embodiment 3.

### Embodiment 3

For example, the CMOS image sensor 10B according to Embodiment 3 can be manufactured as follows.

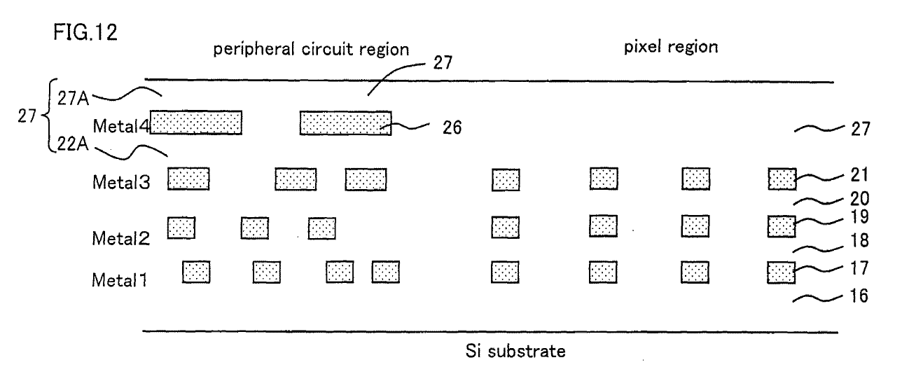

As shown in FIG. 12, four layers of multi-layered wiring layers, which are embedded in the interlayer insulation film, are formed in a peripheral circuit region and in a pixel region, the peripheral circuit region including a driver circuit for controlling the drive of the signal readout circuit, and a pixel region being inside the peripheral circuit region and including the light receiving section 13 for each pixel and the signal readout circuit. Subsequently, the fifth insulation film 27A is polished and planarized by a CMP treatment.

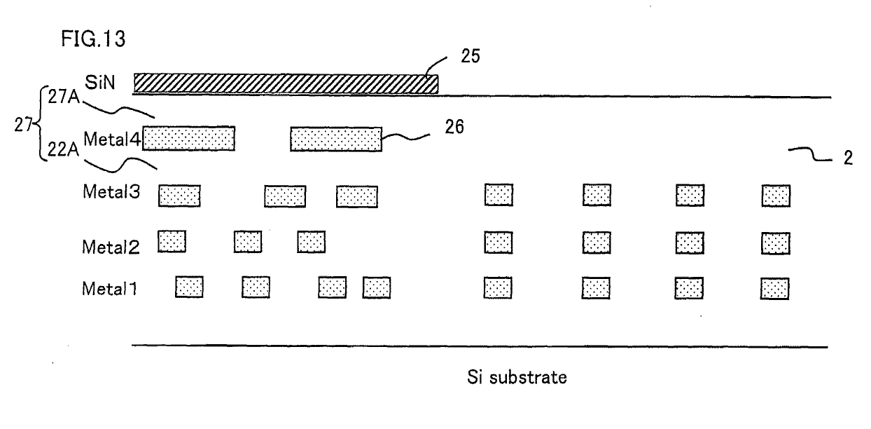

Subsequently, as shown in FIG. 13, the plasma SiN film 25 is formed only in the peripheral circuit region. In the pixel region, the hydrogen sintering process is performed with a thermal treatment of the atmospheric temperature of about 400 to 500 degree Celsius in the atmosphere of hydrogen. Hydrogen permeates into the silicon substrate side and is adsorbed by a silicon dangling bond. As a result, dark current is reduced. At the same time, an ohmic contact is established between the first wiring 17 and an impurity diffusion region on the substrate side (such as the floating diffusion FD).

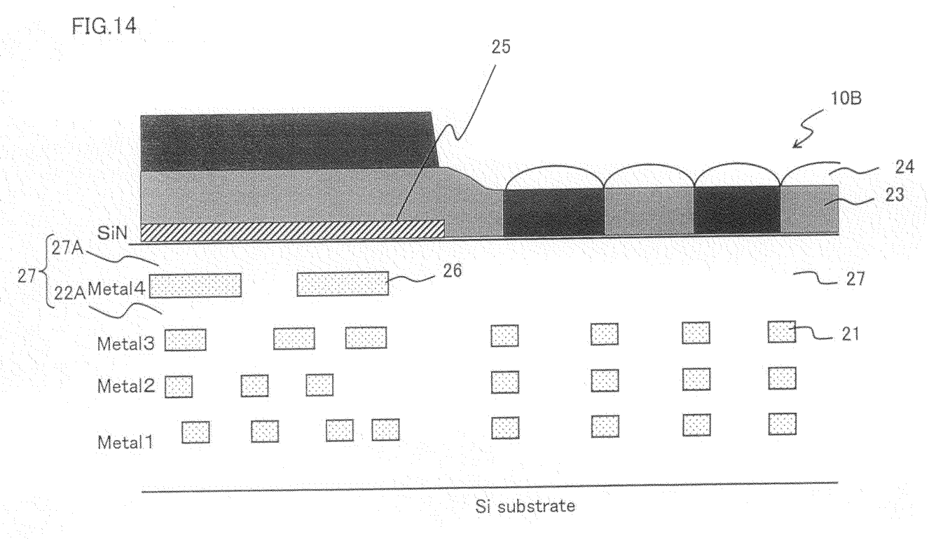

Subsequent to the hydrogen sintering process, as shown in FIG. 14, the color filter 23 arranged for each color is formed directly on the planarized fifth insulation film 27A in the pixel region. The microlens 24 is formed directly on the color filter 23. At this stage, a color filter 23 of one color among a plurality of colors is formed on the planarized fifth insulation film 27A and the plasma SiN film 25, and a color filter 23 of another color among a plurality of colors is formed thereon in the peripheral circuit region. In this case, two layers of color filters 23 of red and blue, for example, are laminated on the plasma SiN film 25 in the peripheral circuit region to shield the light. Thus, the CMOS image sensor 10B according to Embodiment 3 is manufactured. Note that the two layers of color filters 23 of red and blue, which are formed on the plasma SiN film 25 in the peripheral circuit region, may be two layers of color filters 23 of different colors among a plurality of colors (red, blue and green), or may be one layer of a color filter 23 of one color. In addition, instead of two layers of color filters 23 of red and blue, one layer of a color filter of black may be laminated on the plasma SiN film 25 in the peripheral circuit region.

Further, the CMOS image sensor 10B′ according to Embodiment 3 can be manufactured as follows, for example, in a method different from the method described above.

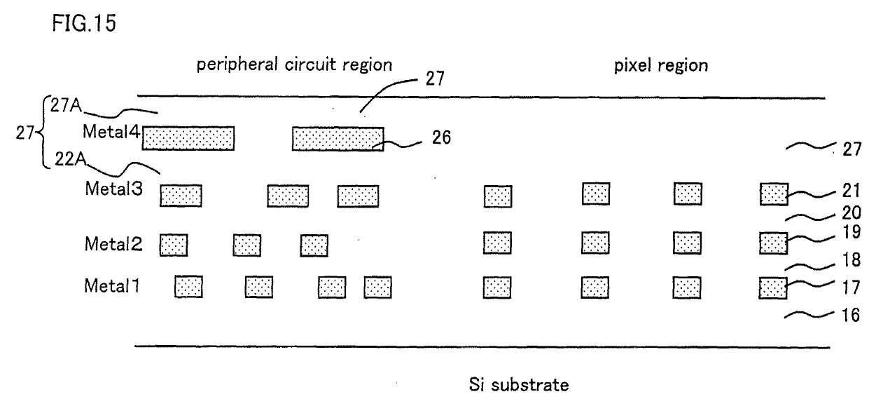

As shown in FIG. 15, four layers of multi-layered wiring layers, which are embedded in the interlayer insulation film, are formed in a peripheral circuit region and in a pixel region, the peripheral circuit region including a driver circuit for controlling the drive of the signal readout circuit, and a pixel region being inside the peripheral circuit region and including the light receiving section 13 for each pixel and the signal readout circuit. Subsequently, the surface of the fifth insulation film 27A is polished and planarized by a CMP treatment. Subsequently, the hydrogen sintering process is performed with a thermal treatment of the atmospheric temperature of about 400 to 500 degree Celsius in the atmosphere of hydrogen, without forming the plasma SiN film 25 in the peripheral circuit region or the pixel region. Hydrogen permeates into the silicon substrate side and is adsorbed to a silicon dangling bond. As a result, dark current is reduced, and at the same time, an ohmic contact is established between the first wiring 17 and an impurity diffusion region on the substrate side (such as the floating diffusion FD).

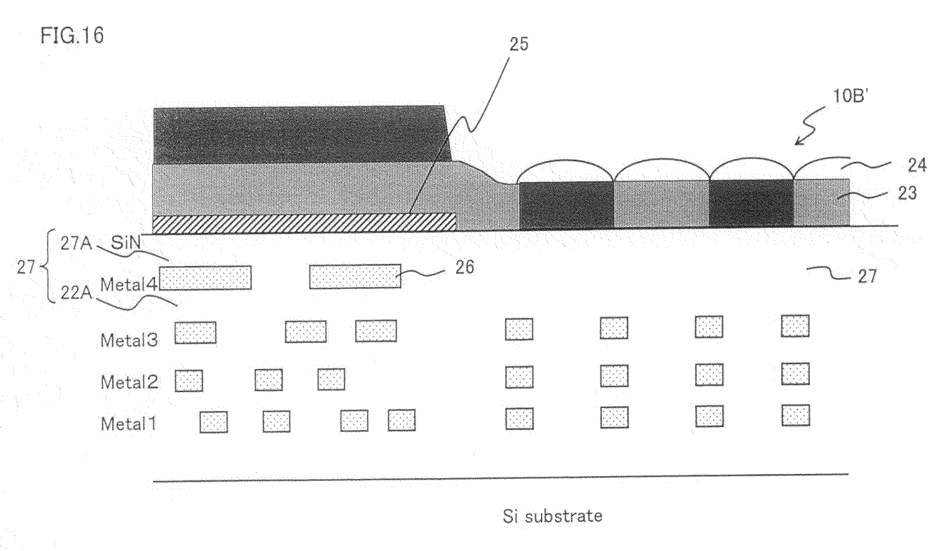

Subsequent to the hydrogen sintering process, as shown in FIG. 16, the color filter 23 arranged for each color is formed directly on the planarized fifth insulation film 27A in the pixel region. The microlens 24 is formed directly on the color filter 23. At this stage, a color filter 23 of one color among a plurality of colors is formed on the planarized fifth insulation film 27A and the plasma SiN film 25, and a color filter 23 of another color among a plurality of colors is formed thereon in the peripheral circuit region. In this case, two layers of color filters 23 of red and blue, for example, are laminated on the plasma SiN film 25 in the peripheral circuit region to shield the light. Thus, the CMOS image sensor 10B′ according to Embodiment 3 is manufactured. Note that the two layers of color filters 23 of red and blue, which are formed on the plasma SiN film 25 in the peripheral circuit region, may be two layers of color filters 23 of different colors among a plurality of colors (red, blue and green), or may be one layer of a color filter 23 of one color. In addition, instead of two layers of color filters 23 of red and blue, one layer of a color filter of black may be laminated on the plasma SiN film 25 in the peripheral circuit region.

According to Embodiment 3 with the structure described above, when the plasma SiN film 25 is not provided and the hydrogen sintering process is performed in the hydrogen atmosphere, the step of forming the plasma SiN film 25 is omitted, so that the number of steps can be reduced and the cost of manufacture can be reduced. Besides, similar to the cases in Embodiments 1 and 2, the multiple reflections of light resulted from the plasma SiN film is reduced between the microlens 24 and the substrate surface so as to control the color irregularity and sensitivity irregularity. At the same time, the outward reflection and transmission of incident light due to the plasma SiN film are eliminated. The distance between the microlens 24 and the substrate surface is further reduced due to the absence of the conventional SiON film and the plasma SiN film (not shown), so that the light receiving sensitivity is improved.

### Embodiment 4

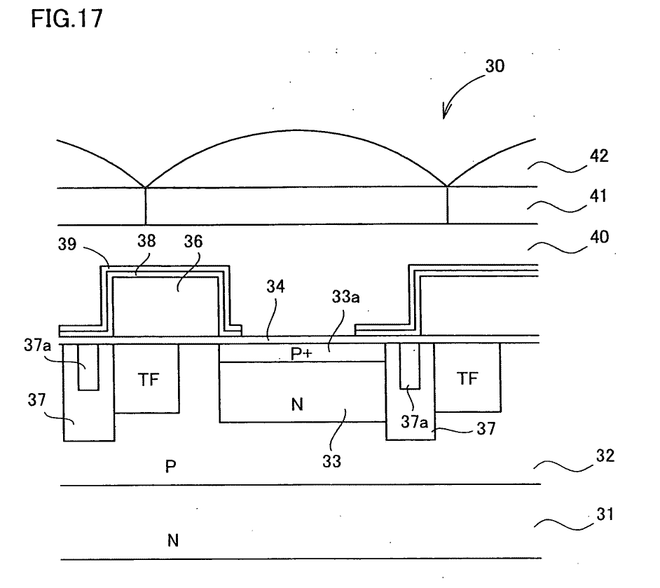

FIG. 17 is a longitudinal cross sectional view schematically showing a unit pixel of a solid-state image capturing device in a CCD image sensor according to Embodiment 4 of the present invention.

In each unit pixel of a CCD image sensor 30 according to Embodiment 4 in FIG. 17, a P-type well region 32 is provided on a substrate section of an N-type semiconductor substrate 31, and an N-type layer of a light receiving section 33 is provided in the P-type well region 32. A photodiode, which functions as a photoelectric conversion section for photoelectrically converting incident light to generate a signal charge, is formed by the P-type well region 32 and the N-type layer. In addition, a surface P+ layer 33a for preventing dark current is provided on a surface of the N-type layer of the light receiving section 33, and the N-type layer of the light receiving section 33 has an embedded structure. Adjacent to the photodiode functioning as a light receiving element, a charge readout section 32a (transistor channel section) for transferring an electric charge from the light receiving section 33 to a charge transfer section TF is formed by the P-type well region 32.

A gate 36 is consecutively arranged in a predetermined direction (vertical transfer direction) on the charge transfer section TF and the charge readout section 32a, having a gate insulation film 34 arranged therebetween. The gate 36 functions as a charge transfer electrode of a CCD structure for reading out a signal charge from the light receiving section 33 and controlling the transferring of the charge in a predetermined direction.

Further, in such a manner to surround along the region of a unit pixel that is constituted of the light receiving section 33 and the gate 36, a high concentration P-type layer 37 (stopper section) for separating elements that have higher impurity concentration than that of the P-type well region 32, and an STI 37a, an insulation region for separating elements, at the center of the width direction are provided by being embedded by a predetermined depth from the surface side.

Thus, the N-type layer of the light receiving section 33 is embedded inside by the surface P+ layer 34, the gate 36 and the high concentration P-type layer 37.

A shield film 39, which is composed of a metal material such as tungsten, is formed on the gate 36 with an insulation film 38 arranged therebetween, and has an opening above the N-type layer of the light receiving section 33. A transparent interlayer insulation film 40 is formed thereon and a planarization is performed.

A color filter 41 arranged for each color is directly provided on the planarized interlayer insulation film 40, and a microlens 42 is directly provided on the interlayer insulation film 40.

For example, the CCD image sensor 30 according to Embodiment 4 can be manufactured as follows.

First, the interlayer insulation film 40 is formed on the substrate section, where the aforementioned N-type layer of the light receiving section 33, the charge transfer section TF, the gate 36, the high concentration P-type layer 37 (stopper section) for separating elements, the shield film 39 and the like are formed. At this stage, the interlayer insulation film 40 embeds unevenness of the gate 36 and the shield film 39 and is planarized. On the interlayer insulation film 40, a silicon oxide film (SiO₂ film) is formed as the interlayer insulation film 40.

That is, in the peripheral circuit region including a driver circuit for drive-controlling a charge transfer electrode having a CCD structure for controlling the transfer of electric charges in a predetermined direction (vertical and horizontal directions), and in the pixel region including the light receiving section 13 for each pixel and a charge transfer electrode having a CCD structure, the surface of the interlayer insulation film 40 is polished to be planarized by the CMP treatment.

Subsequently, the plasma SiN film (not shown) is formed on the planarized interlayer insulation film 40, the plasma SiN film having a function as a passivation film, which prevents the passing of any substances, such as water and a positive ion, that have a harmful influence to a transistor region, and performing as a hydrogen supply source for reducing dark current at the time of sinter process. Further, a hydrogen sintering process is performed with a thermal treatment of the atmospheric temperature of about 400 to 500 degree Celsius. As a result, hydrogen from the plasma SiN film (not shown) is adsorbed by a silicon dangling bond on the silicon substrate so that the occurrence of dark current is reduced on the surface of the substrate.

Further, subsequent to the hydrogen sintering process, the plasma SiN film (not shown) is removed by etching so as to keep the plasma SiN film (not shown) only in the peripheral circuit region.

Further, the color filter 41 arranged for each color is directly formed on the planarized interlayer insulation film 40 in the pixel region. The microlens 42 is directly formed on the color filter 41. As a result, the CCD image sensor 30 according to Embodiment 4 is manufactured.

According to Embodiment 4 with the structure described above, the conventional SiON film for preventing reflection and plasma SiN film for a passivation and hydrogen sinter are not provided. Therefore, the multiple reflections of light resulted from the plasma SiN film (not shown) is eliminated between the microlens 42 and the substrate surface, so that the color irregularity and the sensitivity irregularity are controlled. Further, the transmissivity of the incident light is improved. At the same time, the outward reflection of the incident light does not occur, and the distance between the microlens 42 and the substrate surface is further reduced due to the absence of the conventional SiON film and the plasma SiN film, so that an Airy's disk radius becomes smaller, and the light collection efficiency and the light receiving sensitivity are improved.

The outward reflection of the incident light will be described herein. Due to the provision of the plasma SiN film (not shown), the light that has passed from the microlens 42 to the color filter 41 (refractive index of 1.6) is reflected by the plasma SiN film (refractive index of 2.0), so that incident light is wasted outwardly. However, if the plasma SiN film is not provided, the reflection hardly takes place at the interface between the color filter 41 (refractive index of 1.6) and the underneath interlayer insulation film 40 (silicon oxide film; refractive index of 1.5). Therefore, such a wasting of incident light will not occur and the incident light can be efficiently utilized.

Compared to the conventional case having the plasma SiN film, with n defined as the refractive index difference and 0.4>n≧0, the incident light can be used more efficiently than the conventional case. As a material that has a refractive index similar to the refractive index of the color filter 41, a low dielectric film may be used as the interlayer insulation films 40 instead of the silicon oxide film. The light receiving sensitivity can be improved with this structure, as well.

Further, the controlling effect for the dark current will be maintained and will not be deteriorated because the hydrogen sintering process is performed using the plasma SiN film. In addition, there is no problem regarding the effect for blocking water to the substrate side because the color filter 41 and the microlens 42, both of which have a passivation effect, are provided even if the plasma SiN film functioning as a passivation film is not provided.

Further, when the conventional color filter is provided, such a color filter not only has a thick film, but also has steps underneath. Because of the steps, the incident light reflects diffusely and outwardly, so that the incident light is wasted and a cross talk to adjacent pixels may also occur. However, the present invention does not have such steps and planarization is performed for all the layers below the color filter. Therefore, there is no outward reflection or reflection to the adjacent pixels of the incident light due to such steps, and the incident light is not wasted and a cross talk to adjacent pixels does not occur either.

Although not specifically described in Embodiment 4, instead of the hydrogen sintering process using the plasma SiN film, Embodiment 3, where the hydrogen sintering process is performed in a hydrogen atmosphere, can be also applied.

### Embodiment 5

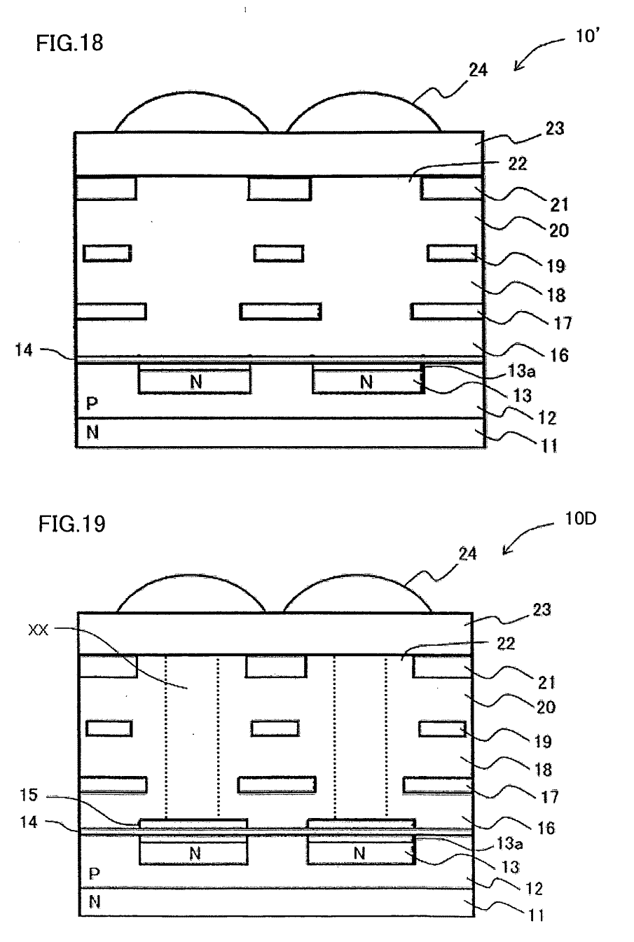

FIG. 18 is a longitudinal cross sectional view showing an exemplary essential structure of a CMOS image sensor according to Embodiment 5 of the present invention. The same reference numerals are used for the structural members that indicate the same functional effects as those of the structural members in FIG. 1.

In a CMOS image sensor 10′ according to Embodiment 5 in FIG. 18, a P-type well region 12 is provided on an N-type semiconductor substrate 11. A plurality of light receiving sections 13 are arranged at a predetermined interval in a two dimensional matrix in the P-type well 12, the light receiving sections 13 functioning as a plurality of N-type photoelectric conversion storing section (each pixel section; light receiving element). A surface P+ layer 13a for preventing dark current is provided on the surface of each light receiving section 13, having a light receiving element (photodiode) embedded structure. A gate insulation film 14, which is a SiO₂ film, is provided on the entire substrate. A SiN film 15 is not provided as a reflection preventing film for reducing reflection on a light receiving surface of the light receiving section 13, on the gate insulation film 14 for each light receiving section 13, in contrast to FIGS. 1 and 6.

If either the third wiring 21 and the interlayer insulation film 22 or the interlayer insulation film 22 is provided directly below the color filter for each color while the plasma SiN film 25 for passivation and hydrogen sintering process is removed, the outward reflection of the incident light resulted from the plasma SiN film 25, and the transmissivity are reduced. At the same time, the distance between the microlens 24 and the substrate surface is further reduced, and the light receiving sensitivity is improved.

### Embodiment 6

In Embodiment 6, a case where a waveguide tube structure (optical fiber structure) is provided in an interlayer insulation film of a CMOS image sensor.

FIGS. 19 to 21 each are longitudinal cross sectional views showing exemplary essential structures of a CMOS image sensor according to Embodiment 6 of the present invention. The same reference numerals are used for the structural members that indicate the same functional effects as those of the structural members in FIGS. 1 and 18.

In FIG. 19, a CMOS image sensor 10D according to Embodiment 6 is a case where a waveguide tube XX is provided for the interlayer insulation film 16 of the CMOS image sensor in FIG. 1. In the interlayer insulation films 16, 18, 20 and 22, which are located between the SiN film 15 and the color filter 23 above the light receiving section 13 that constitutes the photodiode, the waveguide tube XX is formed, the waveguide tube XX formed of a transparent material such as silicon oxide that has a higher refractive index than the interlayer insulation films 16, 18, 20 and 22. It is possible to provide a void on a side wall of the waveguide tube XX and guide incident light from the microlens 24 to the light receiving section 13 by the total reflection of the light inside the surface of the void. It is also possible to provide a multi-layer film and a metal material film and guide incident light from the microlens 24 to the light receiving section 13 by reflecting the incident light on the inner surface of the multi-layer film and the metal material film.

For example, the refractive index of the interlayer insulation films 16, 18, 20 and 22 directly below the center portion of the microlens 24 can be set higher than the refractive index of the interlayer insulation films 16, 18, 20 and 22 directly below the peripheral portion of the microlens 24 so as to turn the portion into the waveguide tube XX. For example, when a transparent, silicon oxide film is formed by plasma CVD, the refractive index can be increased even for the same silicon oxide film by changing conditions for forming a film, such as a treatment temperature and a condition for the amount of flowing gas.

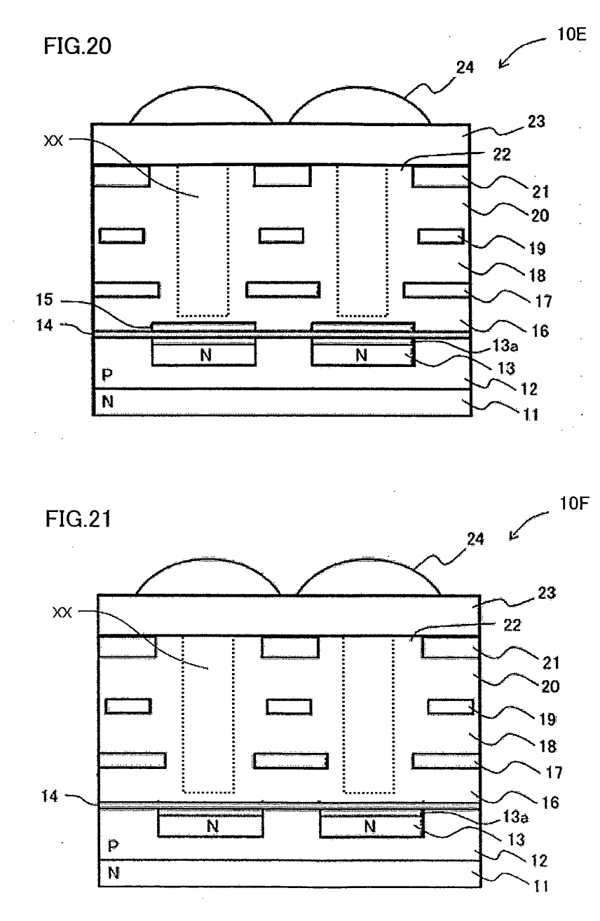

FIG. 20 is a case with a variation of a CMOS image sensor 10E, where the waveguide tube XX is provided on the interlayer insulation film 16 for a predetermined film-thickness on the SiN film 15. In addition, FIG. 21 is a case with another variation of a CMOS image sensor 10F, where the waveguide tube XX is provided on the interlayer insulation film 16 for a predetermined film-thickness on the gate insulation film 14 on the light receiving section 13 in the CMOS image sensor 10′ in FIG. 18 with no SiN film 15 provided. In any case, it is preferable to perform etching on the interlayer insulation film 16 for a predetermined film-thickness to form a hole for the waveguide because the hole will not be engraved too deep.

### Embodiment 7

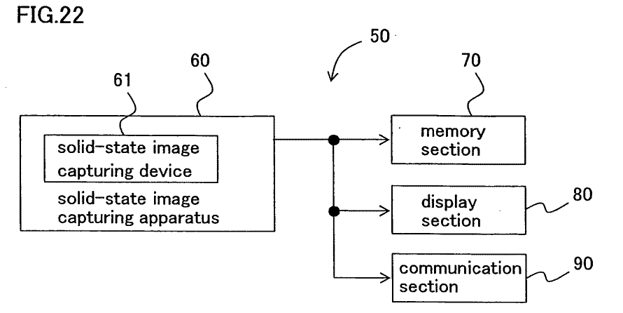

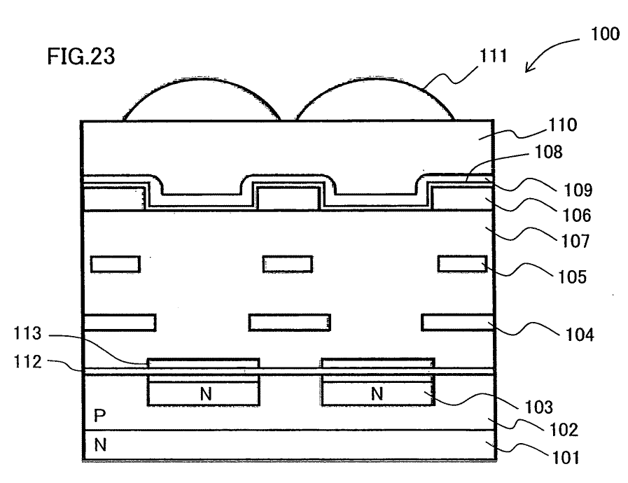

FIG. 22 is a block diagram showing, as Embodiment 7 of the present invention, an exemplary diagrammatic structure of an electronic information device using any of the solid-state image capturing device according to Embodiments 1 to 6 of the present invention in an image capturing section.

In FIG. 22, an electronic information device 50 according to Embodiment 7 includes: a solid-state image capturing apparatus 60 for performing a predetermined signal processing on a color image capturing signal from a solid-state image capturing device 61, for example, according to Embodiments 1 to 6 described above; a memory section 70 (e.g., recording media) for data-recording a high-quality color image data obtained by the solid-state image capturing apparatus 60 after a predetermined signal process is performed on the image data for recording; a display section 80 (e.g., liquid crystal display device) for displaying this color image data from the solid-state image capturing apparatus 60 on a display screen (e.g., liquid crystal display screen) after a predetermined signal process is performed for display; and a communication section 90 (e.g., transmitting and receiving device) for communicating this color image data from the solid-state image capturing apparatus 60 after a predetermined signal process is performed on the image data for communication. Further, the electronic information device 50 may include any of: the memory section 70, the display section 80, and the communication section 90, other than the case where all of the memory section 70, the display section 80, and the communication section 90 are included.

With the electronic information device 50, an electronic device having an image input device is conceivable, such as a digital camera (e.g., digital video camera and digital still camera), a monitoring camera, a door phone camera, an image input camera (e.g., a car equipped camera and a television telephone camera), a scanner, a facsimile machine and a camera-equipped cell phone device.

Therefore, according to Embodiment 7, based on color image signals from the solid-state image capturing apparatus 60, the electronic information device 50 of the present invention is capable of displaying the color image signals on a display screen finely, printing out the color image signals finely on paper by an image output apparatus, communicating the color image signals finely for communication data via wire or radio, storing the color image signals finely by performing a predetermined data compression process on the memory section 70, and performing various data processes finely.

Although a selection transistor is not specifically described in Embodiments 1 to 6 described above, the signal readout circuits among the light receiving elements arranged in a matrix on the side of the semiconductor substrate includes a selection transistor for selecting a predetermined light receiving element, an amplifying transistor, which is connected to the selection transistor in series, for amplifying a signal voltage in accordance with a signal voltage, into which a signal charge being transferred from a selected light receiving element through a transfer transistor to a charge detection section is converted, and a reset transistor for resetting an electric potential of a charge detection section to a predetermined electric potential after the amplifying transistor outputs a signal. But, the present invention is not limited to this, and there is also a case where the selection transistor is not provided in the CMOS image sensor. In such a case, the signal readout circuits among the light receiving elements arranged in a matrix on the side of the semiconductor substrate includes an amplifying transistor for amplifying a signal voltage in accordance with a signal voltage, into which a signal charge being transferred from a light receiving element selected by a selection signal from a peripheral circuit through a transfer transistor to a charge detection section is converted, and a reset transistor for resetting an electric potential of a charge detection section to a predetermined electric potential after the amplifying transistor outputs a signal.

As described above, the present invention is exemplified by the use of its preferred Embodiments 1 to 7. However, the present invention should not be interpreted solely based on Embodiments 1 to 7 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 7 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a solid-state image capturing device, which is a semiconductor image sensor such as a CMOS image sensor and a CCD image sensor, that is constituted of semiconductor elements for performing photoelectric conversion on image light from a subject and capturing an image of the subject; a manufacturing method for the solid-state image capturing device, and an electronic information device, such as a digital camera (e.g., digital video camera and digital still camera), an image input camera, a scanner, a facsimile machine and a camera-equipped cell phone device, having the solid-state image capturing device as an image input device used in an image capturing section of the electronic information device. According to the present invention, the SiON film for preventing reflection and the plasma SiN film, for example, that functions as a passivation and hydrogen sintering process film are either removed or not provided. Therefore, the problem of the outward reflection of incident light resulted from the plasma SiN film having a high refractive index, and the problem of the decrease of the transmission amount due to the plasma SiN film itself are solved. At the same time, the distance between the microlens and the substrate surface is further reduced to improve the light receiving sensitivity. Further, the multiple reflections of light between the microlens and the substrate surface are further reduced to control the color irregularity and the sensitivity irregularity.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state image capturing device including: a plurality of light receiving elements arranged on a surface section of a semiconductor substrate; a color filter of each color for each of the plurality of light receiving elements having an interlayer insulation film arranged therebetween; and a plurality of microlenses for condensing incident light into each of the plurality of light receiving elements,
wherein the interlayer insulation film is provided directly below the color filter of each color in a state where a passivation and hydrogen sintering process film on interlayer insulation film is removed.

2. A solid-state image capturing device according to claim 1, wherein a plurality of multiple wiring layers are buried in the interlayer insulation film.

3. A solid-state image capturing device according to claim 2, wherein the interlayer insulation film is planarized up to and including a surface of an upper most layer of the multiple wiring layers.

4. A solid-state image capturing device according to claim 2, wherein the interlayer insulation film is planarized with a predetermined film-thickness retained above the surface of the upper most layer of the multiple wiring layers.

5. A solid-state image capturing device according to claim 1, wherein
a pixel region, which includes the plurality of light receiving elements, and a peripheral circuit region, which is arranged around the pixel region and includes a driving circuit for selecting and signal-reading of the plurality of light receiving elements, are provided on the same chip;
the passivation and hydrogen sintering process film is provided without being removed between the color filter of each color and the interlayer insulation film in the peripheral circuit region; and
the passivation and hydrogen sintering process film is removed and the interlayer insulation film is provided directly below the color filter of each color in the pixel region.

6. A solid-state image capturing device according to claim 1, wherein when a refractive index difference between the color filter and the interlayer insulation film directly below the color filter is defined as n, such that the n is 0.4>n≧0.

7. A solid-state image capturing device according to claim 6, wherein the interlayer insulation film is a transparent material that has the same refractive index as the color filter.

8. A solid-state image capturing device according to claim 7, wherein the interlayer insulation film is a silicon oxide film or a low dielectric film.

9. A solid-state image capturing device according to claim 1, wherein the passivation and hydrogen sintering process film is a plasma SiN film.

10. A solid-state image capturing device according to claim 5, wherein the passivation and hydrogen sintering process film is a plasma SiN film.

11. A solid-state image capturing device according to claim 1, wherein the solid-state image capturing device is a CMOS solid-state image capturing device, in which a plurality of signal readout circuits are provided for each unit pixel section, the plurality of signal readout circuits are connected to each other by the multiple wiring layers, for selecting the light receiving elements and outputting a signal from the light receiving elements.

12. A solid-state image capturing device according to claim 11, wherein the plurality of signal readout circuits among the light receiving elements arranged in a matrix on the side of the semiconductor substrate includes: a selection transistor for selecting a predetermined light receiving element; an amplifying transistor, which is connected to the selection transistor in series, for amplifying a signal voltage in accordance with a signal voltage, into which a signal charge being transferred from a selected light receiving element through a transfer transistor to a charge detection section is converted; and a reset transistor for resetting an electric potential of a charge detection section to a predetermined electric potential after the amplifying transistor outputs a signal.

13. A solid-state image capturing device according to claim 11, wherein the signal readout circuits among the light receiving elements arranged in a matrix on the side of the semiconductor substrate include: an amplifying transistor for amplifying a signal voltage in accordance with a signal voltage, into which a signal charge being transferred from a light receiving element selected from a peripheral circuit through a transfer transistor to a charge detection section is converted; and a reset transistor for resetting an electric potential of a charge detection section to a predetermined electric potential after the amplifying transistor outputs a signal.

14. A solid-state image capturing device according to claim 1, wherein a reflection preventing film is provided only above the light receiving element and having an insulation film arranged therebetween, and the interlayer insulation film is provided on the reflection preventing film.

15. A solid-state image capturing device according to claim 1, wherein the interlayer insulation film is directly provided above the light receiving element, having an insulation film arranged therebetween.

16. A solid-state image capturing device according to claim 14, wherein a waveguide tube is provided in the interlayer insulation film above the light receiving element so as to guide light from the microlens to the light receiving element.

17. A solid-state image capturing device according to claim 15, wherein a waveguide tube is provided in the interlayer insulation film above the light receiving element so as to guide light from the microlens to the light receiving element.

18. A solid-state image capturing device according to claim 1, wherein the solid-state image capturing device is a CCD solid-state image capturing device, in which the plurality of light receiving elements are provided in two dimensions in a pixel region, and a signal charge photoelectrically converted in the light receiving elements is read out to a charge transfer section and is successively transferred in a predetermined direction.

19. A manufacturing method for a solid-state image capturing device including a plurality of light receiving elements arranged on a surface section of a semiconductor substrate, a color filter of each color for each of the plurality of light receiving elements having an interlayer insulation film arranged therebetween, and a plurality of microlenses each for condensing incident light into each of the plurality of light receiving elements, the method comprising the steps of:
forming a passivation and hydrogen sintering process film on the interlayer insulation film to perform a hydrogen sintering process, or performing a hydrogen sintering process in a hydrogen atmosphere without forming a passivation and hydrogen sintering process film on the interlayer insulation film; and
removing the passivation and hydrogen sintering process film when the passivation and hydrogen sintering process film is formed on the interlayer insulation film.

20. A manufacturing method for a solid-state image capturing device according to claim 19, the method comprising:
a planarization process step of polishing and planarizing an upper most insulation layer of an interlayer insulation film down to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements,
a hydrogen sintering process step of forming a passivation and hydrogen sintering process film on the whole substrate of the planarized insulation layer and performing a hydrogen sintering process by thermal treatment,
a passivation and hydrogen sintering process film removing step of removing the passivation and hydrogen sintering process film in the pixel region by etching the passivation and hydrogen sintering process film in the pixel region with the passivation and hydrogen sintering process film retained in the peripheral circuit region after the hydrogen sintering process, and
a color filter and microlens forming step of, in the pixel region, forming the color filter of each color directly on the planarized insulation layer and forming the microlens further on the color filter.

21. A manufacturing method for a solid-state image capturing device according to claim 19, the method comprising:
a planarization process step of polishing and planarizing an upper most insulation layer of an interlayer insulation film with a predetermined film-thickness retained to a surface of an upper most wiring layer so as to planarize the upper most insulation layer after the multiple wiring layers buried, in the interlayer insulation film in a pixel region, which includes the plurality of light receiving elements, and in a peripheral circuit region, which is arranged around the pixel region and includes a driving circuit for selecting and signal-reading of the plurality of light receiving elements,
a hydrogen sintering process step of forming a passivation and hydrogen sintering process film on the whole substrate of the planarized insulation layer and performing a hydrogen sintering process by thermal treatment,
a passivation and hydrogen sintering process film removing step of removing the passivation and hydrogen sintering process film in the pixel region by etching the passivation and hydrogen sintering process film in the pixel region with the passivation and hydrogen sintering process film retained only in the peripheral circuit region after the hydrogen sintering process, and
a color filter and microlens forming step of, in the pixel region, forming the color filter of each color directly on the planarized insulation layer and forming the microlens further on the color filter.

22. A manufacturing method for a solid-state image capturing device according to claim 19, the method comprising:
a planarization process step of polishing and planarizing an upper most insulation layer of an interlayer insulation film for a predetermined film-thickness retained to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements,
a hydrogen sintering process step of forming a passivation and hydrogen sintering process film only on the peripheral circuit region and performing a hydrogen sintering process by thermal treatment, and
a color filter and microlens forming step of, in the pixel region, forming the color filter of each color directly on the planarized insulation layer and forming the microlens further on the color filter after the hydrogen sintering process.

23. A manufacturing method for a solid-state image capturing device according to claim 19, the method comprising:
a planarization process step of polishing and planarizing an upper most insulation layer of an interlayer insulation film with a predetermined film-thickness retained to a surface of an upper most wiring layer after the multiple wiring layers buried in the interlayer insulation film, in a pixel region, which includes the plurality of light receiving elements, and in a peripheral circuit region, which is arranged around the pixel region and includes a driving circuit for selecting and signal-reading of the plurality of light receiving elements,
a hydrogen sintering process step of performing a hydrogen sintering process in a hydrogen atmosphere by thermal treatment without forming a passivation and hydrogen sintering process film on the peripheral circuit region and the pixel region, and
a color filter and microlens forming step of, in the pixel region, forming the color filter of each color directly on the planarized insulation layer and forming the microlens further on the color filter after the hydrogen sintering process.

24. An electronic information device using the solid-state image capturing device according to claim 1 as an image input device in an image capturing section.
